(19) United States
(12) Patent Application Publication
(10) Pub. No.: US 2025/0079420 A1
(43) Pub. Date: Mar. 6, 2025

(54) MODULE

(71) Applicant: Murata Manufacturing Co., Ltd., Kyoto-fu (JP)

(72) Inventor: Yoshihito OTSUBO, Nagaokakyo-shi (JP)

(21) Appl. No.: 18/953,810

(22) Filed: Nov. 20, 2024

Related U.S. Application Data
(63) Continuation of application No. PCT/JP2023/016269, filed on Apr. 25, 2023.

(30) Foreign Application Priority Data
Jun. 7, 2022 (JP) 2022-092306

(51) Int. Cl. H01L 25/16; H01L 23/538

(52) U.S. Cl. CPC H01L 25/162; H01L 23/5385; H01L 23/5386; H10D 1/68

(57) ABSTRACT

A module includes a core substrate provided with a first surface and a second surface that define front and rear surfaces, respectively, the core substrate being provided with a through hole that connects the first surface and the second surface to each other, a redistribution layer arranged to cover the first surface and the through hole of the core substrate, a first component at least partially arranged in the inside of the through hole, and a second component mounted on a side of the second surface of the core substrate as partially being superimposed on the through hole. The first component is electrically connected to the redistribution layer. The first component is electrically directly connected to the second component in a portion where the second component is superimposed on the through hole.

### CROSS REFERENCE TO RELATED APPLICATION

This is a continuation of International Application No. PCT/JP2023/016269 filed on Apr. 25, 2023 which claims priority from Japanese Patent Application No. 2022-092306 filed on Jun. 7, 2022. The contents of these applications are incorporated herein by reference in their entireties.

### BACKGROUND OF THE DISCLOSURE

### Field of the Disclosure

The present disclosure relates to a module.

### Description of the Related Art

Japanese Patent No. 5934154 discloses a substrate structure on which an electronic component is mounted. This substrate structure includes a substrate provided with a through hole, a first electronic component, and a second electronic component. The first electronic component is arranged in such a state that a part or the entirety thereof is located in the inside of the through hole. The inside of the through hole around the first electronic component is filled with a filler. The second electronic component is connected to the first electronic component.

Japanese Patent Laid-Open No. 2007-311766 discloses a multilayer substrate. This multilayer substrate includes a first layer, a second layer, and a third layer. The multilayer substrate is provided with a recess so as to pass through the first layer. A lower-tier mount component is accommodated in this recess. An upper-tier mount component is arranged on an upper surface of the multilayer substrate.

### BRIEF SUMMARY OF THE DISCLOSURE

In PTL 1, a thickness of the substrate is sufficiently larger than a dimension of the first electronic component, and overall reduction in profile is not sufficiently achieved. Though the lower-tier mount component is accommodated in the recess in the multilayer substrate in PTL 2, this recess has a depth merely corresponding to a thickness of the first layer, and hence a degree of reduction in profile is low in view of the entire multilayer substrate. Therefore, neither of PTLs 1 and 2 is sufficient in reduction in profile of the entire module. Not only reduction in profile but also space saving is demanded in some cases.

A possible benefit of the present disclosure is to provide a module that can sufficiently achieve overall reduction in profile or space saving.

In order to achieve the possible benefit, a module based on the present disclosure includes a core substrate provided with a first surface and a second surface that define front and rear surfaces, respectively, the core substrate being provided with a through hole that connects the first surface and the second surface to each other, a redistribution layer arranged to cover the first surface and the through hole of the core substrate, a first component at least partially arranged in the inside of the through hole, and a second component mounted on a side of the second surface of the core substrate as being partially superimposed on the through hole. The first component is electrically connected to the redistribution layer and the first component is electrically directly connected to the second component in a portion where the second component is superimposed on the through hole.

According to the present disclosure, the core substrate is provided with the through hole, at least a part of the first component is arranged in the inside of the through hole, and the first component is electrically directly connected to the redistribution layer. Therefore, the entire module can sufficiently be low in profile. Since the first component and the second component can be arranged as being superimposed on each other, space saving of the entire module can also be achieved.

### BRIEF DESCRIPTION OF THE SEVERAL VIEWS OF THE DRAWINGS

FIG. 1 is a cross-sectional view of a module in a first embodiment based on the present disclosure.

FIG. 2 is a cross-sectional view of a module in a second embodiment based on the present disclosure.

FIG. 3 is a plan view of a module in a third embodiment based on the present disclosure.

FIG. 4 is a cross-sectional view along the line IV-IV in FIG. 3.

FIG. 5 is a cross-sectional view of a first modification of the module in the third embodiment based on the present disclosure.

FIG. 6 is a cross-sectional view of a second modification of the module in the third embodiment based on the present disclosure.

FIG. 7 is a cross-sectional view of a module in a fourth embodiment based on the present disclosure.

FIG. 8 is a cross-sectional view of a module in a fifth embodiment based on the present disclosure.

FIG. 9 is a cross-sectional view of a modification of the module in the fifth embodiment based on the present disclosure.

FIG. 10 is a cross-sectional view of a module in a sixth embodiment based on the present disclosure.

FIG. 11 is a cross-sectional view of a modification of the module in the sixth embodiment based on the present disclosure.

### DETAILED DESCRIPTION OF THE DISCLOSURE

A dimensional ratio shown in the drawings does not necessarily faithfully represent an actual dimensional ratio and a dimensional ratio may be exaggerated for the sake of convenience of description. A concept up or upper or down or lower mentioned in the description below does not mean absolute up or upper or down or lower but may mean relative up or upper or down or lower in terms of a shown position.

### First Embodiment

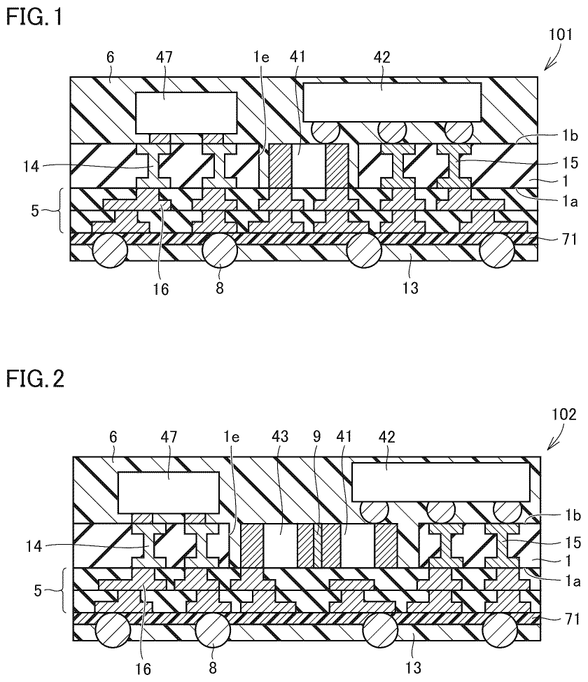

A module in a first embodiment based on the present disclosure will be described with reference to FIG. 1. FIG. 1 shows a cross-sectional view of a module 101 in the present embodiment.

Module 101 includes a core substrate 1, a redistribution layer 5, a first component 41, and a second component 42. Core substrate 1 is provided with a first surface 1a and a second surface 1b that define front and rear surfaces, respectively. Core substrate 1 is provided with a through hole 1e that connects first surface 1a and second surface 1b to each other. Redistribution layer 5 is arranged to cover first surface 1a and through hole 1e of core substrate 1. First component 41 is at least partially arranged in the inside of through hole 1e.

First component 42 is mounted on a side of second surface 1b of core substrate 1 as being partially superimposed on through hole 1e. In other words, a part of second component 42 is superimposed on through hole 1e. First component 41 is electrically connected to redistribution layer 5. First component 41 is connected to redistribution layer 5 without another interconnection being interposed. First component 41 is electrically directly connected to second component 42 in a portion where second component 42 is superimposed on through hole 1e. First component 41 is connected to second component 42 without another interconnection being interposed.

The entire first component 41 may be arranged in the inside of through hole 1e. In the present embodiment, a construction in which the entire first component 41 is arranged in the inside of through hole 1e is shown by way of example. In the present embodiment, first component 41 is a capacitor by way of example. In the present embodiment, first component 41 is in what is called lateral arrangement.

A component 47 is mounted on second surface 1b of core substrate 1. A sealing resin 6 is arranged to cover second surface 1b, second component 42, and component 47. Sealing resin 6 enters also the inside of through hole 1e.

A plurality of connection conductors 16 are arranged in the inside of redistribution layer 5. Connection conductors 14 and 15 are arranged in the inside of core substrate 1 so as to pass through core substrate 1 in a thickness direction. Component 47 is electrically connected to connection conductor 16 in redistribution layer 5 through connection conductor 14. Second component 42 is electrically connected to connection conductor 16 in redistribution layer 5 through connection conductor 15. A solder bump 8 is arranged on a surface of redistribution layer 5 on a side distant from core substrate 1. Solder bump 8 is connected to connection conductor 16. A region not covered with solder bump 8 in the surface of redistribution layer 5 on the side distant from core substrate 1 is covered with a resist layer 71. A surface of resist layer 71 on the side distant from redistribution layer 5 is covered with a resin layer 13. Solder bump 8 is arranged to pass through resist layer 71 and resin layer 13, and solder bump 8 has one end thereof on the side distant from redistribution layer 5 exposed through resin layer 13.

Though FIG. 1 schematically shows connection conductors 14, 15, and 16, they may be formed from combination of a conductor pattern and a conductor via as appropriate. Though connection conductors 14 and 15 are provided with different types of hatching, connection conductors 14 and 15 may be formed of the same material or different materials. Connection conductor 16 may be made of a material the same as or different from the material for connection conductors 14 and 15. Redistribution layer 5 may include a structure in which a plurality of insulating layers are layered. In the example shown in FIG. 1, redistribution layer 5 includes a structure in which two insulating layers are layered. A material for the insulating layer included in redistribution layer 5 is different from the material for core substrate 1.

In the present embodiment, core substrate 1 is provided with through hole 1e, at least a part of first component 41 is arranged in the inside of through hole 1e, and first component 41 is electrically directly connected to redistribution layer 5. Therefore, the entire module can sufficiently be low in profile.

In general, an interconnection between components is a factor for deterioration of characteristics. In order to address this, in the present embodiment, first component 41 is electrically directly connected to second component 42 while it is electrically connected to redistribution layer 5. Therefore, an excess interconnection does not have to be provided and deterioration of the characteristics can be suppressed. Since first component 41 and second component 42 can also be arranged as being superimposed on each other, an area of the entire module can also be saved.

### Second Embodiment

A module in a second embodiment based on the present disclosure will be described with reference to FIG. 2. FIG. 2 shows a cross-sectional view of a module 102 in the present embodiment. Module 102 is common in basic construction to module 101 described in the first embodiment.

In module 102, a third component 43 is arranged in the inside of through hole 1e. Third component 43 is electrically connected to redistribution layer 5. Third component 43 is electrically connected to first component 41. Third component 43 and first component 41 are connected to each other in the inside of through hole 1e. Third component 43 and first component 41 are directly connected to each other through solder 9, without an interconnection being interposed.

In the example shown in FIG. 2, third component 43 is also a capacitor by way of example. In the example shown in FIG. 2, first component 41 and third component 43 are both arranged in lateral arrangement in the inside of through hole 1e. A dimension of first component 41 and third component 43 in the thickness direction of core substrate 1 is the same as a dimension of through hole 1e in the thickness direction. First component 41 includes external terminals on opposing longitudinal ends. Third component 43 is also similar. First component 41 and third component 43 are arranged as being aligned in such a manner that the longitudinal ends thereof are brought closer. The external terminal formed at the end of first component 41 is electrically connected to the external terminal formed at the end of third component 43 through solder 9. First component 41 and third component 43 are thus connected in series.

The present embodiment can also obtain the effect described in the first embodiment. Since first component 41 and third component 43 are arranged as being connected in series in the present embodiment, an excess interconnection does not have to be provided and deterioration of the characteristics can be suppressed. The profile can be low by arrangement of first component 41 and third component 43 in their entirety in the inside of through hole 1e.

In order to interpose a plurality of components between second component 42 and redistribution layer 5, the construction as shown in the present embodiment may be adopted. Though an example in which two components in total, which are first component 41 and third component 43, are arranged in through hole 1e as being connected in series is shown, a larger number of components may be arranged in through hole 1e as being connected in series, without being limited to two components.

### Third Embodiment

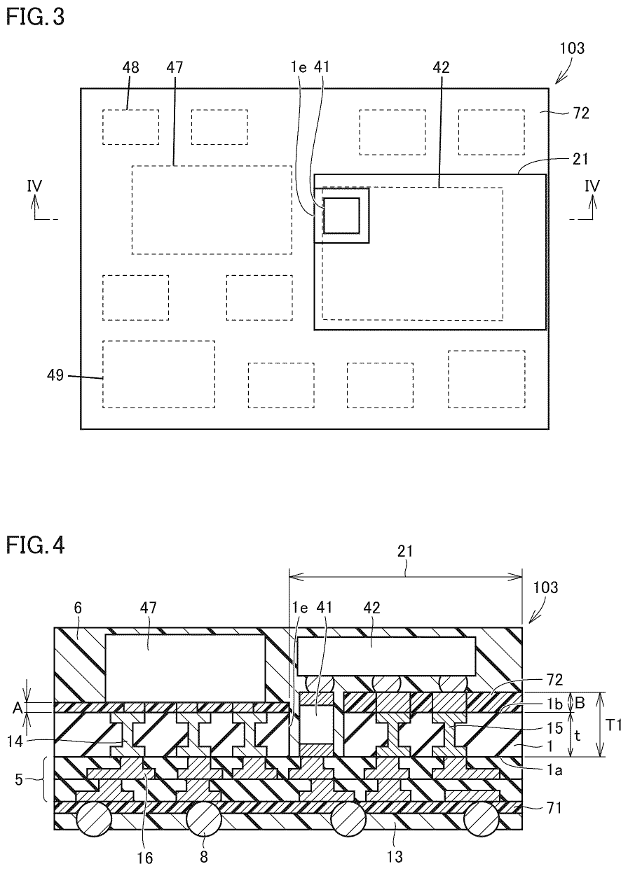

A module in a third embodiment based on the present disclosure will be described with reference to FIGS. 3 to 4. FIG. 3 shows a plan view of a module 103 in the present embodiment. FIG. 3 shows module 103 with a part thereof having been removed, which will be described in detail later. FIG. 4 shows a cross-sectional view along the line IV-IV in FIG. 3. Module 103 is common in basic construction to module 101 described in the first embodiment.

As shown in FIG. 4, second surface 1b of core substrate 1 is covered with a resist layer 72. Some electrodes are arranged to pass through resist layer 72, and second component 42, components 47, 48 and 49, and the like are mounted with the use of these electrodes. Furthermore, second component 42, components 47, 48 and 49, and the like are covered with sealing resin 6. FIG. 3 shows a state, with sealing resin 6, second component 42, components 47, 48 and 49, and the like having been removed, and shows second component 42, components 47, 48 and 49, and the like with a dashed line. Resist layer 72 covers the entire region other than through hole 1e, in second surface 1b of core substrate 1. Resist layer 72 includes a large-thickness region and a small-thickness region. Though resist layer 72 is formed to a thickness A in principle, resist layer 72 is formed to a thickness B in a region 21 shown in FIG. 3. Thickness B is larger than thickness A. Region 21 includes the entirety of a region corresponding to projection of second component 42.

As shown in FIG. 4, first component 41 is arranged in through hole 1e in what is called vertical arrangement. Specifically, first component 41 is arranged in such a posture that a longitudinal direction thereof coincides with the thickness direction of core substrate 1. A dimension of first component 41 in the thickness direction of core substrate 1 is larger than a thickness t of core substrate 1. A total thickness of thickness t of core substrate 1 and thickness B of resist layer 72 in region 21 is denoted as T1. Thickness T1 is equal to the dimension of first component 41 in the thickness direction of core substrate 1. Thickness T1 and the dimension of first component 41 in the thickness direction of core substrate 1 are not necessarily exactly equal to each other, but may substantially be equal to each other.

In the present embodiment, the dimension of first component 41 in the thickness direction of core substrate 1 is larger than thickness t of core substrate 1 in a portion on an outer periphery of through hole 1e superimposed on second component 42, resist layer 72 is arranged between second surface 1b and second component 42, and an end surface of first component 41 on the side of second surface 1b is flush with the surface of resist layer 72 in the region superimposed on second component 42. “Thickness t of core substrate 1 in the portion on the outer periphery of through hole 1e superimposed on second component 42” is defined for the purpose as below. With attention being paid to the entire perimeter of the outer periphery of through hole 1e, in an example where core substrate 1 is varied in thickness in the entire perimeter, attention is paid to the thickness of core substrate 1 in the portion on the outer periphery of through hole 1e superimposed on second component 42. In the example shown in FIG. 4, core substrate 1 has thickness t equal on both of the left side and the right side of through hole 1e. If core substrate 1 is different in thickness between the left side and the right side of through hole 1e, however, the thickness of core substrate 1 in the portion superimposed on second component 42, that is, on the right side of through hole 1e, is considered as the reference. The dimension of first component 41 in the thickness direction of core substrate 1, that is, a dimension in a vertical direction in FIG. 4, is larger than the thickness of core substrate 1 on the right side of through hole 1e.

Second component 42 includes a plurality of terminals on a surface on the side of core substrate 1. At least one of these terminals is connected to first component 41, and remaining terminals are connected to connection conductor 15 through the electrodes exposed at resist layer 72 in region 21.

Since the first component is arranged in the inside of the through hole in the core substrate in vertical arrangement in the present embodiment, space saving can be achieved. Furthermore, in the present embodiment, even when first component 41 is arranged as extending off through hole 1e, the plurality of electrodes connected to the terminals of second component 42 can be positioned on the same plane by making resist layer 72 larger in thickness than other portions as necessary, which allows adaptation also to an example in which the dimension of first component 41 in the thickness direction of core substrate 1 is larger than thickness t of core substrate 1.

An example as below may also be applicable as a modification of the module in the present embodiment.

### First Modification

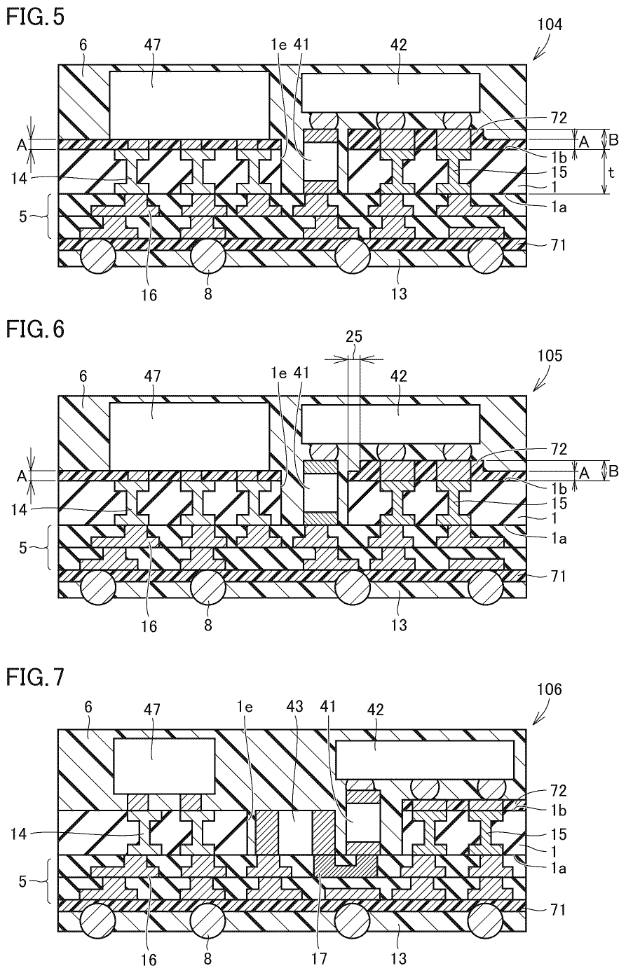

FIG. 5 shows a module 104 as a first modification of the module in the third embodiment. In module 104, thickness A of resist layer 72 in an outer peripheral portion of second surface 1b is smaller than thickness B of resist layer 72 in the region superimposed on second component 42. If resist layer 72 keeps a large thickness also at the end of second surface 1b, separation of resist layer 72 may be likely. When resist layer 72 is small in thickness in the outer peripheral portion of second surface 1b as in module 104, however, separation of resist layer 72 can be less likely.

### Second Modification

FIG. 6 shows a module 105 as a second modification of the module in the third embodiment. Though module 105 is similar in basic construction to module 104, resist layer 72 is small in thickness also in the vicinity of through hole 1e in module 105. In other words, even in the inside of region 21 superimposed on second component 42, in a region 25 in the vicinity of through hole 1e, resist layer 72 has thickness A smaller than thickness B.

### Fourth Embodiment

A module in a fourth embodiment based on the present disclosure will be described with reference to FIG. 7. FIG. 7 shows a cross-sectional view of a module 106 in the present embodiment. Module 106 is common in basic construction to module 101 described in the first embodiment.

In module 106, third component 43 other than first component 41 is arranged in the inside of through hole 1e. Third component 43 is electrically connected to redistribution layer 5. Third component 43 is arranged in lateral arrangement. First component 41 is arranged in vertical arrangement. Third component 43 is electrically connected to first component 41. Third component 43 and first component 41 are electrically connected to each other through an interconnection 17 provided in the inside of redistribution layer 5.

First component 41 is, for example, a capacitor. First component 41 includes what is called a side electrode as an external electrode. A main body of first component 41 has a geometry in a parallelepiped shape formed by layering of insulating layers. The “side electrode” is formed by dipping prescribed opposing ends of the main body in a conductive paste and solidifying the conductive paste attached to the main body to cover opposing ends of the main body. When attention is paid to the external electrode located at an upper end of first component 41 shown in FIG. 7 by way of example, this external electrode includes a portion that covers an upper end of a side surface facing front on the sheet plane, a portion that covers an upper end of a side surface facing the rear on the sheet plane, a portion that covers an upper end of a side surface facing the right in the figure, a portion that covers an upper end of a side surface facing the left in the figure, and a portion that covers the entire side surface facing straight up. In other words, this single external electrode includes five portions in total and extends on five different surfaces. In general, the portion that covers the entire side surface facing straight up among the portions extending on these five respective surfaces is largest in area.

In the present embodiment, first component 41 is in vertical arrangement, and hence a surface large in area of the external electrode of first component 41 faces second component 42. In other words, first component 41 includes the external electrode that lies across a plurality of surfaces thereof, and it is arranged in such a posture that the area of the external electrode arranged on the surface that faces second component 42 is largest.

The present embodiment can also obtain the effect described in the first embodiment. In addition, since the first component is arranged in vertical arrangement, space saving can also be achieved.

In particular, in the present embodiment, first component 41 includes the external electrode that lies across the plurality of surfaces and first component 41 is arranged in such a posture that the area of the external electrode arranged on the surface facing second component 42 is largest. Therefore, a large area of junction in electrical connection between first component 41 and second component 42 can be secured. Therefore, electrical connection between first component 41 and second component 42 is stabilized.

### Fifth Embodiment

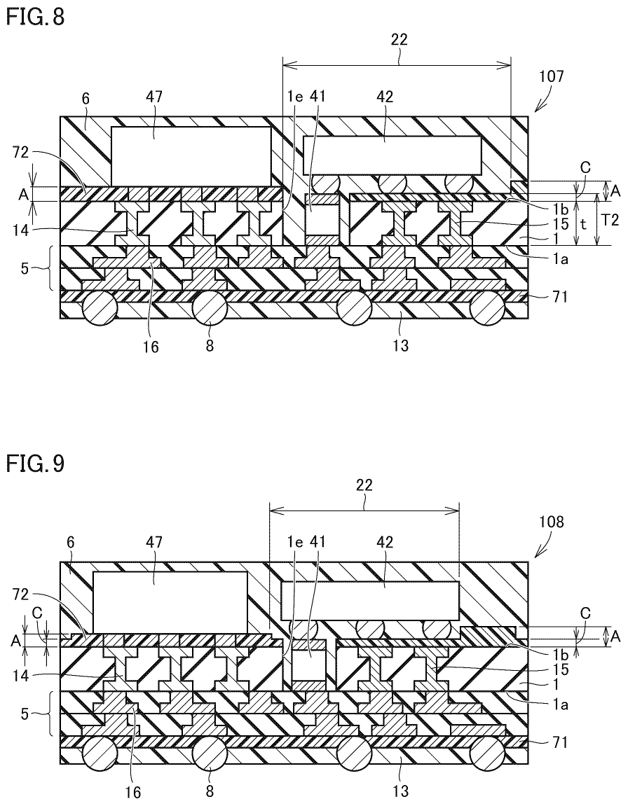

A module in a fifth embodiment based on the present disclosure will be described with reference to FIG. 8. FIG. 8 shows a cross-sectional view of a module 107 in the present embodiment. Module 107 is common in basic construction to module 101 described in the first embodiment.

In module 107, resist layer 72 includes a large-thickness region and a small-thickness region. Though resist layer 72 is formed to thickness A in principle, resist layer 72 is formed to a thickness C in a region 22 shown in FIG. 8. Thickness C is smaller than thickness A.

As shown in FIG. 8, in through hole 1e, first component 41 is arranged in what is called vertical arrangement. A total thickness of thickness t of core substrate 1 and thickness C of resist layer 72 in region 22 is denoted as T2. Thickness T2 is equal to the dimension of first component 41 in the thickness direction of core substrate 1. Thickness T2 and the dimension of first component 41 in the thickness direction of core substrate 1 are not necessarily exactly equal to each other, but may substantially be equal to each other.

In the present embodiment, the dimension of first component 41 in the thickness direction of core substrate 1 is larger than thickness t of core substrate 1 in the portion on the outer periphery of through hole 1e superimposed on second component 42, resist layer 72 is arranged between second surface 1b and second component 42, and the end surface of first component 41 on the side of second surface 1b is flush with the surface of resist layer 72 in the region superimposed on second component 42.

In the present embodiment, even when first component 41 is arranged as extending off through hole 1e, the plurality of electrodes connected to the terminals of second component 42 can be positioned on the same plane by adjustment of the thickness of resist layer 72 as necessary, which allows adaptation to an example in which the dimension of first component 41 in the thickness direction of core substrate 1 is larger than thickness t of core substrate 1. Adjustment of the thickness of resist layer 72 is not limited to making the thickness larger than in other regions, but the thickness may be made smaller than in other regions as shown in the present embodiment. The present embodiment can thus also obtain the effect described in the first or third embodiment.

### Modification

FIG. 9 shows a module 108 as a modification of the module in the fifth embodiment. In module 108, thickness C of resist layer 72 in the outer peripheral portion of second surface 1b is smaller than the thickness of resist layer 72 in the region superimposed on second component 42. When resist layer 72 keeps a large thickness also at the end of second surface 1b, separation of resist layer 72 may be likely. When resist layer 72 is small in thickness in the outer peripheral portion of second surface 1b as in module 108, however, separation of resist layer 72 can be less likely.

### Sixth Embodiment

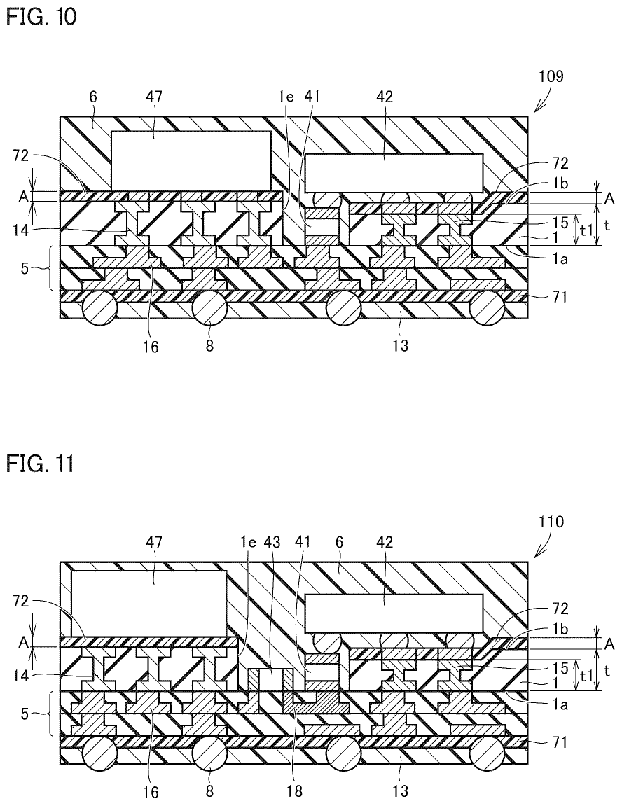

A module in a sixth embodiment based on the present disclosure will be described with reference to FIG. 10. FIG. 10 shows a cross-sectional view of a module 109 in the present embodiment. Module 109 is common in basic construction to module 101 described in the first embodiment.

In module 109, there is a large-thickness region and a small-thickness region in core substrate 1. Though core substrate 1 is formed to thickness t in principle, it has a thickness t1 in a region below second component 42. Thickness t1 is smaller than thickness t. Resist layer 72 has a constant thickness regardless of whether or not it is located in the region below second component 42, and has thickness A.

The construction of module 109 can also be expressed as below. In module 109, core substrate 1 includes a first region having first thickness t and a second region having a second thickness t1 different from the first thickness. Second component 42 is superimposed on the second region. In the example shown in FIG. 10, the region in core substrate 1 having thickness t is the first region. The region in core substrate 1 having second thickness t1 below second component 42 is the second region. Resist layer 72 extends on at least a part of the first region and at least a part of the second region. The dimension of first component 41 in the thickness direction of core substrate 1 is closer to a thickness calculated by addition of second thickness t1 to the thickness of resist layer 72 in the second region than to a thickness calculated by addition of first thickness t to the thickness of resist layer 72 in the first region.

In the present embodiment, even when first component 41 is arranged as extending off through hole 1e, the plurality of electrodes connected to the terminals of second component 42 can be positioned on substantially the same plane by locally changing the thickness of core substrate 1 as necessary. Though a surface of an upper terminal of first component 41 is strictly not flush with the upper surface of resist layer 72 in FIG. 10, they can be positioned at heights close to each other to some extent. Therefore, second component 42 can be mounted astride both of them.

Adaptation to an example in which the dimension of first component 41 in the thickness direction of core substrate 1 is greatly different from basic thickness t of core substrate 1 can thus also be achieved. The present embodiment can thus also obtain the effect described in the first or third embodiment.

Though the thickness of core substrate 1 is locally made smaller to thickness t1 below second component 42 in the present embodiment, this is merely by way of example. Though relation of t>t1 is satisfied, that is, the second thickness is smaller than the first thickness, in this example, this relation may be opposite. If a difference in height between the surface of the upper terminal of first component 41 and the upper surface of resist layer 72 can be reduced, for example, by local increase in thickness of core substrate 1 below second component 42, such local increase in thickness may be made.

### Modification

FIG. 11 shows a module 110 as a modification of the module in the sixth embodiment. In module 110, third component 43 other than first component 41 is arranged in the inside of through hole 1e. Third component 43 is electrically connected to redistribution layer 5. Third component 43 is arranged in lateral arrangement. First component 41 is arranged in vertical arrangement. Third component 43 is electrically connected to first component 41. Third component 43 and first component 41 are electrically connected to each other through an interconnection 18 provided in the inside of redistribution layer 5.

A plurality of embodiments of the embodiments above may be adopted in combination as appropriate.

The embodiments disclosed herein are illustrative and non-restrictive in every respect. The scope of the present disclosure is defined by the terms of the claims and includes any modifications within the scope and meaning equivalent to the terms of the claims.

### Additional Aspect 1

A module includes a core substrate provided with a first surface and a second surface that define front and rear surfaces, respectively, the core substrate being provided with a through hole that connects the first surface and the second surface to each other, a redistribution layer arranged to cover the first surface and the through hole of the core substrate, a first component at least partially arranged in the inside of the through hole, and a second component mounted on a side of the second surface of the core substrate as being partially superimposed on the through hole, the first component is electrically connected to the redistribution layer, and the first component is electrically directly connected to the second component in a portion where the second component is superimposed on the through hole.

### Additional Aspect 2

In the module according to Additional Aspect 1, a dimension of the first component in a thickness direction of the core substrate is larger than a thickness of the core substrate in a portion on an outer periphery of the through hole superimposed on the second component, a resist layer is arranged between the second surface and the second component, and an end surface of the first component on the side of the second surface is flush with a surface of the resist layer in a region superimposed on the second component.

### Additional Aspect 3

In the module according to Additional Aspect 2, a thickness of the resist layer in an outer peripheral portion of the second surface is smaller than the thickness of the resist layer in the region superimposed on the second component.

### Additional Aspect 4

In the module according to Additional Aspect 2, the core substrate includes a first region having a first thickness and a second region having a second thickness different from the first thickness, the second component is superimposed on the second region, and the resist layer extends on at least a part of the first region and at least a part of the second region, and the dimension of the first component in the thickness direction of the core substrate is closer to a thickness calculated by addition of the second thickness to a thickness of the resist layer in the second region than a thickness calculated by addition of the first thickness to the thickness of the resist layer in the first region.

### Additional Aspect 5

In the module according to any one of Additional Aspects 1 to 4, a third component is arranged in the inside of the through hole, the third component is electrically connected to the redistribution layer, and the third component is electrically connected to the first component.

### Additional Aspect 6

In the module according to any one of Additional Aspects 1 to 5, the first component includes an external electrode that lies across a plurality of surfaces of the first component, and the first component is arranged in such a posture that an area of the external electrode arranged on a surface facing the second component is largest.

1 core substrate; 1a first surface; 1b second surface; 1e through hole; 5 redistribution layer; 6 sealing resin; 8 solder bump; 9 solder; 13 resin layer; 14, 15, 16 connection conductor; 17, 18 interconnection; 21, 22, 25 region; 41 first component; 42 second component; 43 third component; 47, 48, 49 component; 71, 72 resist layer; 101, 102, 103, 104, 105, 106, 107, 108, 109, 110 module.

1. A module comprising:
a core substrate provided with a first surface and a second surface, the first surface and the second surface defining front and rear surfaces, respectively, the core substrate being provided with a through hole connecting the first surface and the second surface to each other;
a redistribution layer arranged to cover the first surface and the through hole of the core substrate;
a first component at least partially arranged in inside of the through hole; and
a second component mounted on a side of the second surface of the core substrate as being partially superimposed on the through hole, wherein
the first component is electrically connected to the redistribution layer, and
the first component is electrically directly connected to the second component in a portion where the second component is superimposed on the through hole.

2. The module according to claim 1, wherein
a dimension of the first component in a thickness direction of the core substrate is larger than a thickness of the core substrate in a portion on an outer periphery of the through hole superimposed on the second component,
a resist layer is arranged between the second surface and the second component, and
an end surface of the first component on the side of the second surface is flush with a surface of the resist layer in a region superimposed on the second component.

3. The module according to claim 2, wherein
a thickness of the resist layer in an outer peripheral portion of the second surface is less than a thickness of the resist layer in the region superimposed on the second component.

4. The module according to claim 2, wherein
the core substrate includes a first region having a first thickness and a second region having a second thickness different from the first thickness,
the second component is superimposed on the second region, and
the resist layer extends on at least a part of the first region and at least a part of the second region, and the dimension of the first component in the thickness direction of the core substrate is closer to a thickness calculated by addition of the second thickness to a thickness of the resist layer in the second region than a thickness calculated by addition of the first thickness to the thickness of the resist layer in the first region.

5. The module according to claim 1, wherein
a third component is arranged in the inside of the through hole,
the third component is electrically connected to the redistribution layer, and
the third component is electrically connected to the first component.

6. The module according to claim 1, wherein
the first component includes an external electrode lying across a plurality of surfaces of the first component, and
the first component is arranged in such a posture that an area of the external electrode arranged on a surface facing the second component is largest.

7. The module according to claim 2, wherein
a third component is arranged in the inside of the through hole,
the third component is electrically connected to the redistribution layer, and
the third component is electrically connected to the first component.

8. The module according to claim 3, wherein
a third component is arranged in the inside of the through hole,
the third component is electrically connected to the redistribution layer, and
the third component is electrically connected to the first component.

9. The module according to claim 4, wherein
a third component is arranged in the inside of the through hole,
the third component is electrically connected to the redistribution layer, and
the third component is electrically connected to the first component.

10. The module according to claim 2, wherein
the first component includes an external electrode lying across a plurality of surfaces of the first component, and
the first component is arranged in such a posture that an area of the external electrode arranged on a surface facing the second component is largest.

11. The module according to claim 3, wherein
the first component includes an external electrode lying across a plurality of surfaces of the first component, and
the first component is arranged in such a posture that an area of the external electrode arranged on a surface facing the second component is largest.

12. The module according to claim 4, wherein
the first component includes an external electrode lying across a plurality of surfaces of the first component, and
the first component is arranged in such a posture that an area of the external electrode arranged on a surface facing the second component is largest.

13. The module according to claim 5, wherein
the first component includes an external electrode lying across a plurality of surfaces of the first component, and
the first component is arranged in such a posture that an area of the external electrode arranged on a surface facing the second component is largest.
